(19) United States
(12) Patent Application Publication
(10) Pub. No.: US 2005/0014364 A1
(43) Pub. Date: Jan. 20, 2005

(54) Method of suppressing the effect of shining spots present at the edge of a wafer

(75) Inventors: Xiaochun Linda Chen, Mechanicsville, VA (US); Kangguo Cheng, Beacon, NY (US); Mai Randall, Harriman, NY (US)

Correspondence Address: LERNER, DAVID, LITTENBERG,;KRUMHOLZ & MENTLIK, 600 SOUTH AVENUE WEST, WESTFIELD, NJ, 07090, US

(73) Assignees: Infineon Technologies North America Corp., San Jose, CA (US); International Business Machines Corporation, Armonk, NY (US)

(21) Appl. No.: 10/622,607

(22) Filed: Jul. 18, 2003

(51) Int. Cl. H01L 21/302; B32B 5/12; H01L 21/44; H01L 21/8242

(52) U.S. Cl. 438/671; 438/736; 430/312; 438/243

(57) ABSTRACT

Devices formed in a substrate are protected from shining spots present in a periphery of the substrate. A ring of material is formed on the substrate to separate the periphery of the substrate from a further region of the substrate where the devices are formed.

### BACKGROUND OF THE INVENTION

The present invention is directed to semiconductor devices and, more particularly, to methods of fabricating semiconductor devices.

As semiconductor devices have become increasingly smaller, prevention of the contamination of the processing tools and exposure tools used to fabricate the devices has become more critical to avoid the introduction of defects on the semiconductor devices which reduce process yields. As an example, dynamic random access memory (DRAM) devices are prone to reduced yields caused by particulate contamination generated by “shining spots” formed at the periphery of the wafer.

The shining spots are exposed silicon regions formed at the edge of the wafers. DRAM devices typically include a semiconductor memory cell array formed of a plurality of memory cells arranged in rows and columns which are connected by a plurality of bit lines as well as a plurality of word lines. For vertical device memory cells, each cell is comprised of a deep trench region wherein a trench capacitor and a vertical transistor are formed. Each deep trench also divides an active area region. The bit lines contact the active area regions on each side of a deep trench at locations where the active area regions form the drains of the vertical transistors. The word lines pass between the active area regions at locations above the deep trench regions, namely where the active area regions are interrupted, to contact the gates of the vertical transistors formed within the deep trenches.

To form the deep trenches, a pad oxide layer and a pad nitride layer are successively deposited atop a substrate, and then a hard mask layer is deposited atop the nitride layer. A layer of photoresist or other resist is deposited atop the hard mask layer and is then exposed and developed in a known manner and used to mask the patterning of the hard mask layer as well as the pad nitride layer and the pad oxide layer. Next, the hard mask layer is used to mask the etching of the deep trench, and the hard mask layer is then removed.

While the deep trench is etched, the shining spots are often formed at the periphery of the wafer, typically about 3-4 mm from the edge of the wafer. The shining spots result from a center-to-edge loading effect during the reactive ion etch (RIE) of the deep trench which causes a higher etch rate of the hard mask layer in the regions nearer to the edge of the right wafer than at the center of the wafer. As a result, some or all of the hard mask layer is removed in the regions near the edge of the wafer and exposes the underlying silicon in these regions during at least part of the deep trench etch. The exposed silicon regions near the edge of the wafer are known as “shining spots”. The exposed silicon is prone to being broken off and cause particulate contamination on the various process and exposure tools that are used to carry out the subsequent processing steps. The particulates may be transferred, while the wafer is within the process tool or exposure tool, onto a device region on the wafer and create defects which may cause the device to fail. As a result, the process yield of the devices is diminished.

It is therefore desirable to provide a process that reduces the particulate contamination caused by the shining spots.

### SUMMARY OF THE INVENTION

The present invention limits the effects of the shining spots that are present at the edge of the wafer by providing a ring of resist or other organic material at the periphery of the wafer to separate the device areas of the wafer from the edge of the wafer where the shining spots are located.

In accordance with an aspect of the invention, devices formed in a substrate are protected from shining spots present in a periphery of the substrate. A ring of material is formed atop the substrate to separate the periphery of the substrate from a further region of the substrate wherein the devices are formed.

According to another aspect of the invention, at least one device is formed in a substrate. A layer of resist is deposited atop the substrate. The layer of resist is patterned to form a ring of resist atop the substrate. The ring of resist separates a periphery of the substrate from a further region of the substrate, thereby protecting devices formed in the further region of the substrate from shining spots present in the periphery atop the substrate. A further layer of resist is deposited on the substrate. The further layer of resist is patterned to form at least one patterned region within the further region of the substrate.

According to yet another aspect of the invention, a semiconductor device is formed in a substrate in the manner described above.

According to a further aspect of the invention, at least one device is formed in a substrate. A pad oxide layer is deposited atop the substrate, and a pad nitride layer is deposited atop the pad oxide layer. A hard mask layer is deposited atop the pad nitride layer, and a layer of resist is deposited atop the hard mask layer. The layer of resist is patterned to form a ring of resist which separates a periphery of the substrate from a further region of the substrate, thereby protecting devices formed in the further region of the substrate from shining spots present in the periphery of the substrate. A further layer of resist is deposited atop the hard mask layer and atop the ring of resist, and the further layer of resist is patterned to form at least one patterned region within the further region of the substrate. The ring of resist is of sufficient thickness that a region of the further layer of resist that is atop the ring of resist is not patterned. The hard mask layer is etched using the patterned further layer of resist and the ring of resist as an etch mask. At least one trench region in the substrate is etched using the hard mask layer and the ring of resist as an etch mask. The ring of resist is of sufficient thickness such that a region of the hard mask layer that is beneath the ring of resist remains after the trench region is etched.

The foregoing aspects, features and advantages of the present invention will be further appreciated when considered with reference to the following description of the preferred embodiment and accompanying drawings.

### BRIEF DESCRIPTION OF THE DRAWINGS

FIG. 1 is a diagram showing a known device layout on a substrate in which a device array region directly contacts the shining spot region located at the edge of the wafer.

FIGS. 2A-2F are diagrams showing a cross-sectional view of a wafer which is processed in accordance with the invention.

FIG. 3 is a diagram showing a layout of a wafer in which the array area is isolated from the shining spot region at the edge of the wafer in accordance with the invention.

### DETAILED DESCRIPTION

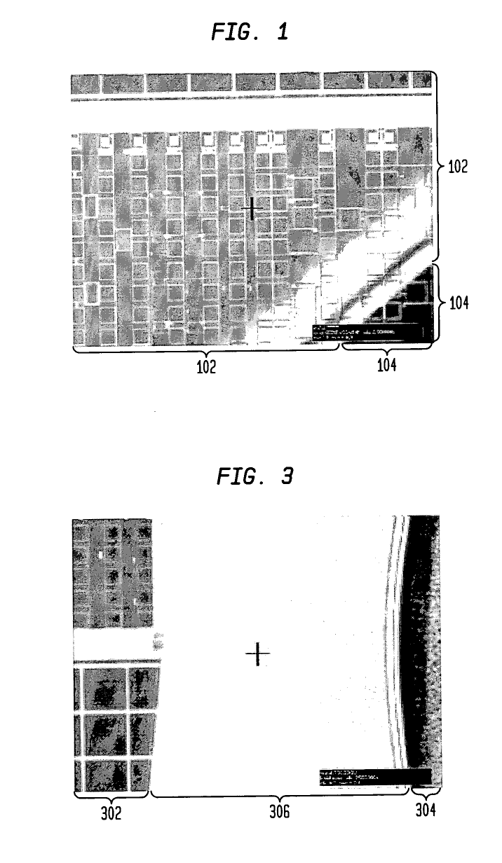

FIG. 1 shows a known layout of a portion of a wafer. A vertical DRAM device, or other device, is formed in an array area 102 of the wafer. A plurality of shining spots are formed in an edge region 104 of the wafer. The array region 102 and the edge region 104 are adjacent to one another so that contamination from particulates that break off from the shining spot regions are transferred onto the device features of the array regions 102. The particulates are typically about the same size or of greater size than the feature sizes of the devices in the array region and therefore cause defects and device failures that reduce the process yields.

The present invention therefore provides a ring of resist or other organic materials that separates the array region from the periphery of the wafer and protects the array area from the shining spots of the wafer edge.

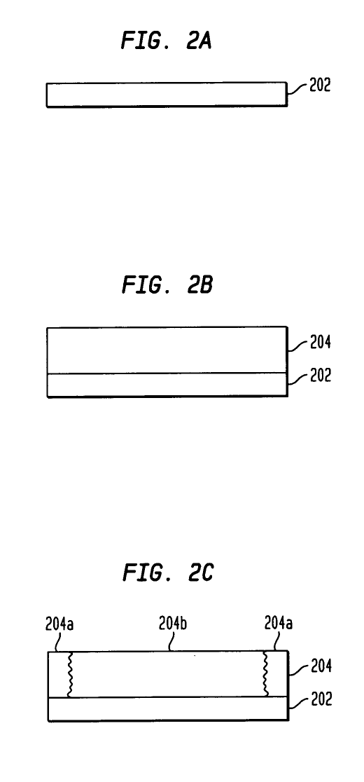

FIGS. 2A-2F illustrate the steps of a process according to the invention.

FIG. 2A shows a cross-section of a hard mask layer 202 that is formed atop a substrate (not shown), which may be a pad nitrate layer formed over a pad oxide layer and over a silicon substrate as described above. A resist layer 204, such as a photoresist or other resist, is deposited atop the layer 202. Then, as FIG. 2C shows, a portion of the resist is exposed in a known manner, such as by transmitting light through one or more openings in a mask into a projection lens to focus a pattern onto the substrate. When the resist is a negative resist, the periphery region 204a is exposed so that the unexposed region 204b may be subsequently removed when the resist is developed. Alternatively, when the resist is a positive resist, the region 204b is exposed and is removed when the resist is developed so that only the periphery region 204a remains. FIG. 2D illustrates the resist ring 206 that remains after the exposure and development steps.

Then, as FIG. 2E shows, a further layer of resist 208 is deposited atop the exposed regions of the layer 202 as well as atop the resist ring 206. Next, as shown in FIG. 2F, the resist layer 208 is patterned in a known manner to form features 210 in the device regions. The resist ring 206 raises the height of the resist layer 208 above the plane of exposure so that no patterns are formed in the resist layer 208 that is deposited atop the resist ring 206. Moreover, any patterns that may be formed in the portion of the resist layer 208 that is deposited atop the resist ring 206 will not be transferred through the thick resist ring onto the hard mask layer.

Then, the patterned resist features 210 serve to mask the etching of the hard mask layer 202 as does the resist ring 206. The second resist layer 208 may then be removed, but the resist ring 206 remains so that during subsequent deep trench etching, the portion of the hard mask layer at the periphery of the wafer is protected by the resist ring which prevents the removal of the hard mask layer in these regions, thereby preventing the formation of shining spots. Moreover, any shining spots that are formed at the edge of the wafer are isolated from the device regions.

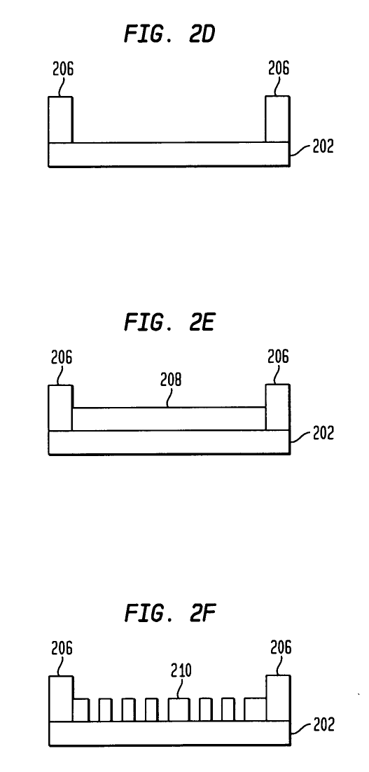

FIG. 3 shows a top view of a layout of a wafer. A device region 302 is isolated from the edge of the wafer 304, where shining spots are formed, by a separation region 306 which is formed beneath the resist ring 206, shown in FIG. 2. The separation between the shining spots and the device region protects against the transfer of particulates generated in the shining spot regions onto the device region, and reduces the generation of defects. As a result, device yields is increased.

Alternatively, a ring of resist, or other organic material, is deposited directly onto the periphery of the wafer to form the ring 206 shown in FIG. 2D without a lithographic step. Then, the further resist layer 208 may be deposited and patterned as shown in FIGS. 2E and 2F.

Advantageously, the invention avoids the formation of shining spots near the edge of the wafer and protects from the effects of any shining spots that are formed at the edge of the wafer. As a result, fewer defects are formed in the device regions of the wafer, so that the device yields increases and reduces the production costs of the devices.

Although the invention herein has been described with reference to particular embodiments, it is to be understood that these embodiments are merely illustrative of the principles and applications of the present invention. It is therefore to be understood that numerous modifications may be made to the illustrative embodiments and that other arrangements may be devised without departing from the spirit and scope of the present invention as defined by the appended claims.

1. A method of protecting devices formed in a substrate from shining spots present in a periphery of said substrate, said method comprising:
forming a ring of material atop said substrate to separate said periphery of said substrate from a further region of said substrate wherein said devices are formed.

2. The method of claim 1 wherein said forming step comprises forming said ring of material atop a hard mask layer that is disposed atop said substrate.

3. The method of claim 1 wherein said forming step comprises depositing material in a region between said periphery of said substrate and said further region of said substrate.

4. The method of claim 1 wherein said forming step comprises depositing material atop all of said substrate and then patterning said material to form said ring of material.

5. The method of claim 1 wherein said ring of material includes at least one of a resist layer and another organic material.

6. The method of claim 1 wherein said substrate is silicon.

7. A method of forming at least one device in a substrate, said method comprising:
depositing a layer of resist atop said substrate;
patterning said layer of resist to form a ring of resist atop said substrate, said ring of resist separating a periphery of said substrate from a further region of said substrate thereby protecting devices formed in said further region of said substrate from shining spots present in said periphery of said substrate;
depositing a further layer of resist atop said substrate and atop said ring of resist; and
patterning said further layer of resist to form at least one patterned region within said further region of said substrate.

8. The method of claim 7 further comprising:
depositing a pad oxide layer atop said substrate, depositing a pad nitride layer atop said pad oxide layer, and depositing a hard mask layer atop said nitride layer; and wherein said forming step comprises forming said ring of material atop said hard mask layer.

9. The method of claim 8 further comprising: etching said hard mask layer using said patterned further layer of resist and said ring of resist as an etch mask; and etching at least one trench region in said substrate using said hard mask layer and said ring of resist as an etch mask.

10. The method of claim 9 wherein said ring of resist is of sufficient thickness that a region of said hard mask layer that is beneath said ring of resist remains after said trench region is etched.

11. The method of claim 7 wherein said ring of resist is of sufficient thickness that a region of said further layer of resist that is atop said ring of resist is not patterned during said step of patterning said further layer of resist.

12. The method of claim 7 wherein said layer of resist comprises a negative resist, and said layer of resist is patterned by exposing said ring of resist and then removing an unexposed portion of said resist.

13. The method of claim 7 wherein said layer of resist comprises a positive resist, and said layer of resist is patterned by exposing said layer of resist except for said ring of resist and then removing an exposed portion of said resist.

14. The method of claim 7 wherein said substrate is silicon.

15. A semiconductor device formed in a substrate, said semiconductor device being formed by a method comprising:
depositing a layer of resist atop said substrate;
patterning said layer of resist to form a ring of resist atop said substrate, said ring of resist defining a separation region that separates a periphery of said substrate from a further region of said substrate thereby protecting devices formed in said further region of said substrate from shining spots present in said periphery of said substrate;
depositing a further layer of resist atop said substrate; and
patterning said further layer of resist to form at least one patterned region within said further region of said substrate.

16. The semiconductor device of claim 15 wherein said method further comprises: depositing a pad oxide layer atop said substrate, depositing a pad nitride layer atop said pad oxide layer, and depositing a hard mask layer atop said nitride layer; and wherein said forming step comprises forming said ring of material atop said hard mask layer.

17. The semiconductor device of claim 16 wherein said method further comprises: etching said hard mask layer using said patterned further layer of resist and said ring of resist as an etch mask; and etching at least one trench region in said substrate using said hard mask layer and said ring of resist as an etch mask.

18. The semiconductor device of claim 17 wherein said ring of resist is of sufficient thickness that a region of said hard mask layer that is beneath said ring of resist remains after said trench region is etched.

19. The semiconductor device of claim 15 wherein said ring of resist is of sufficient thickness that a region of said further layer of resist that is atop said ring of resist is not patterned during said step of patterning said further layer of resist.

20. The semiconductor device of claim 15 wherein said layer of resist comprises a negative resist, and said layer of resist is patterned by exposing said ring of resist and then removing an unexposed portion of said resist.

21. The semiconductor device of claim 15 wherein said layer of resist comprises a positive resist, and said layer of resist is patterned by exposing said layer of resist except for said ring of resist and then removing an exposed portion of said resist.

22. The semiconductor device of claim 15 wherein said substrate is silicon.

23. A method of forming at least one device in a substrate, said method comprising:
depositing a pad oxide layer atop said substrate;
depositing a pad nitride layer atop said pad oxide layer;
depositing a hard mask layer atop said nitride layer;
depositing a layer of resist atop said hard mask layer;
patterning said layer of resist to form a ring of resist, said ring of resist separating a periphery of said substrate from a further region of said substrate thereby protecting devices formed in said further region of said substrate from shining spots present in said periphery of said substrate;
depositing a further layer of resist atop said hard mask layer and atop said ring of resist;
patterning said further layer of resist to form at least one patterned region within said further region of said substrate, said ring of resist being of sufficient thickness that a region of said further layer of resist that is atop said ring of resist is not patterned;
etching said hard mask layer using said patterned further layer of resist and said ring of resist as an etch mask; and
etching at least one trench region in said substrate using said hard mask layer and said ring of resist as an etch mask, said ring of resist being of sufficient thickness that a region of said hard mask layer that is beneath said ring of resist remains after said trench region is etched.

24. A semiconductor device formed in a substrate, said semiconductor device being formed by a method comprising:
depositing a pad oxide layer atop said substrate;
depositing a pad nitride layer atop said pad oxide layer;
depositing a hard mask layer atop said nitride layer;
depositing a layer of resist atop said hard mask layer;
patterning said layer of resist to form a ring of resist, said ring of resist defining a separation region that separates a periphery of said substrate from a further region of said substrate thereby protecting devices formed in said further region of said substrate from shining spots present in said periphery of said substrate;
depositing a further layer of resist atop said hard mask layer and atop said ring of resist;
patterning said further layer of resist to form at least one patterned region within said further region of said substrate, said ring of resist being of sufficient thickness that a region of said further layer of resist that is atop said ring of resist is not patterned;
etching said hard mask layer using said patterned further layer of resist and said ring of resist as an etch mask; and
etching at least one trench region in said substrate using said hard mask layer and said ring of resist as an etch mask, said ring of resist being of sufficient thickness that a region of said hard mask layer that is beneath said ring of resist remains after said trench region is etched.

25. A semiconductor device structure formed in a substrate, said semiconductor device structure comprising:
a separation region that separates at least one device region from a periphery of the substrate having shining spots formed therein.
